(19) United States
(12) Patent Application Publication
(10) Pub. No.: US 2024/0397637 A1
(43) Pub. Date: Nov. 28, 2024

(54) ELECTRONICS HOUSING ASSEMBLY

(71) Applicant: Redarc Technologies Pty Ltd, Morphett Vale (AU)

(72) Inventors: Peter William Cosgriff, Morphett Vale (AU); Seth Michael Brady, Hindmarsh (AU)

(21) Appl. No.: 18/685,361

(22) PCT Filed: Aug. 5, 2022
(86) PCT No.: PCT/AU2022/050850

§ 371 Date: Feb. 21, 2024

(30) Foreign Application Priority Data
Aug. 25, 2021 (AU) 2021221637`

(51) Int. Cl. H05K 5/00; H05K 5/06; H05K 7/20

(52) U.S. Cl. CPC H05K 5/0047; H05K 5/061; H05K 7/20418

(57) ABSTRACT

A housing assembly for electronics, the assembly including a rigid base member for mounting at least one printed circuit board thereto, a rigid outer shell, and a flexible inner sealing membrane, the base member and the outer shell together forming an enclosure for the at least one printed circuit board. The flexible membrane includes a sealing portion about its periphery for compression between the base member and the outer shell to seal the enclosure, and also includes a plurality of inwardly projecting, elastically deformable abutments configured to compress against the at least one printed circuit board to provide vibration resistance.

### RELATED APPLICATION

This application claims convention priority from Australian provisional patent application 2021221637 filed on 25 Aug. 2021, the content of which is incorporated herein by reference.

### Technical Field of Invention

This invention relates to housing assemblies suitable for containing electronics, particularly the electronics required for automotive usage, in situations where the ingress of dust or water to the housings is likely but needs to be avoided, and in situations where the housing will be subjected to reasonably significant vibrations that could damage the electronics.

While the use of such housing assemblies will be described below with respect to the automotive industry, it will be appreciated that the housing assembly of the present invention may be used in any situation or environment where vibration and dust/moisture ingress is likely yet undesirable for the housing of electronics.

### BACKGROUND OF INVENTION

The automotive industry today relies heavily on advance electronic systems and circuitry, not only due to the advent of autonomous vehicles and electric vehicles, but also due to the sophistication of traditional vehicles that almost all now include lane and speed control systems, light detection and ranging systems, vehicle-to-vehicle communications and collision avoidance systems, amongst many others.

The housing of printed circuit boards and other electronic systems in a manner that both safely and securely protects those electronics, while also still permitting normal usage of the vehicle with respect to temperature extremes, vehicle vibration, and water and dust influx has thus become an important design element for all types of vehicles, including road and off-road vehicles, and also including towed vehicles. In this respect, towed vehicles, such as caravans, have become just as demanding in terms of their requirements for advanced electronic systems, with comfort levels and access to day-to-day living features being heavily in demand.

Ingress Protection (IP) ratings are now defined in several international standards and are used to define levels of sealing effectiveness of electrical enclosures against intrusion from users (intentional or accidental), foreign bodies (such as tools, dirt and dust) and moisture. An IP5 or IP6 rating (in a system rating from IP1 to IP6) refers to the presence of protection against dust and other particulates, such that any ingress will not damage or impede the satisfactory performance of internal components (IP5) or will provide full protection against dust and other particulates, including by way of a vacuum seal (IP6).

Furthermore, with both IP5 and IP6 ratings, protection against moisture ingress can be rated in accordance with several protection sub-levels (from 1 to 9) with, for example, an IP5/6 or IP6/6 rating indicating protection against powerful jets of directed water from any direction, and an IP5/7 or IP6/7 rating indicating protection for full immersion for up to 30 minutes at depths up to 1 metre with limited ingress and no damage to components. Ratings of IP5/6, IP5/7, IP6/6 and IP6/7 are becoming regarded by the automotive industry as being necessary, or at least preferred, for all electronics housings used in vehicles.

An example of a previous arrangement of an electronics housing is described in US patent publication 2008/0212268A1 (VDO Automotive AG), hereafter the “VDO publication”. The VDO publication relates to a housing system for an electronic device in automobiles and discloses the use of a housing with a top part in the form of a pressure compensation film fixed with adhesive to a bottom part. The film includes a closed ring of adhesive around its edge to provide the sealing with the bottom part, and the system allows for the inclusion of a protective cover. The VDO publication thus describes a system that it contends will reduce dust and moisture ingress but does not attempt to provide vibration resistance for any componentry housed therewithin.

Before turning to a summary of the solution provided by the present invention, it should be appreciated that reference to any prior art in this specification is not, and should not be taken as, an acknowledgment or any form of suggestion that this prior art forms part of the common general knowledge in any country.

Also, the following description will use directional terms such as downward and downwardly, upward and upwardly, and lower and upper, which will be used with reference to the housing assembly of the invention when positioned generally horizontally within, for example, the engine bay of a vehicle. There is, of course, generally no need for such a housing assembly to be positioned horizontally in a vehicle, and housing assemblies often are not installed horizontally, but this language will be used in this specification for ease of description and understanding. Further, there will also be references to inner and outer, and inwardly and outwardly, which will be references made with respect to the interior of the enclosure formed by the housing assembly of the present invention.

### SUMMARY OF INVENTION

The present invention provides a housing assembly for electronics, the assembly including a rigid base member for mounting at least one printed circuit board thereto, a rigid outer shell, and a flexible inner sealing membrane, the base member and the outer shell together forming an enclosure for the at least one printed circuit board, wherein the flexible membrane includes:
a sealing portion about its periphery for compression between the base member and the outer shell to seal the enclosure; and
a plurality of inwardly projecting, elastically deformable abutments configured to compress against the at least one printed circuit board to provide vibration resistance.

In a preferred form, the rigid base member includes a bottom portion, preferably rectangular, whose upper surface provides a printed circuit board mounting surface, with the bottom portion including opposed upstanding side walls and being open at its ends. The side walls preferably include an integrated external heat sink arrangement in the form of elongate heat dissipating fins, the fins configured preferably longitudinally along the exterior of the side walls to assist with heat removal from the enclosure of the housing assembly during use.

In one form, the outer shell is preferably box-shaped, preferably also having a rectangular shape, but with a top portion having downwardly extending perimetric side walls and end walls about its periphery. Preferably, the outer shell's side walls are opposed and are spaced and sized to fit inside the side walls of the base member, with the top portion of the outer shell itself being sized such that its end walls can be positioned adjacent the ends of the bottom portion of the base member such that the base member and the outer shell together form the enclosure of the housing assembly. Therefore, prior to assembly, but with reference to the horizontal orientation referred to above, the box-shape of the outer shell renders the outer shell open downwardly so as to be capable of sitting over and encapsulating, after assembly, whatever electronics are mounted on the PCB mounting surface of the bottom portion of the base member.

In a particularly preferred form, the flexible membrane of the housing assembly of the present invention is also generally rectangular and is also of a downwardly open box-shape. In this form, the flexible membrane will include its own top member with downwardly extending perimetric side walls and end walls about its periphery, all sized to fit, when assembled, within the outer shell. In another form, the flexible membrane will still include its own top member but only with downwardly extending side walls, or only with downwardly extending end walls, or with a combination of some side walls and some end walls, with or without downwardly extending columnar members, again sized to fit, when assembled, within the outer shell and all assisting to support the flexible membrane's sealing portion relative to its top member.

The sealing portion about the periphery of the flexible membrane is for compression between the base member and the outer shell to seal the enclosure when assembled, the sealing portion being an outwardly projecting peripheral sealing flange at the free ends of the walls and/or, if present, the columnar members, of the flexible membrane, the sealing portion being sized and positioned to locate between the free ends of outer shell and the bottom portion of the base member when together, for compression between the base member and the outer shell to seal the enclosure.

Before turning to a description of further advantageous features of the housing assembly of the present invention, it is to be understood that the preferred shapes described above for the different components of the housing assembly (the base member, the outer shell and the flexible membrane) are not the only shapes that a housing assembly in accordance with the present invention might take—the abovementioned shapes (rectangular, box-shaped, opposed side walls and end walls) have been described in order to provide context to the overall description of the invention. A skilled person will understand that other normal shapes for electronic housing assemblies may also be adopted with the present invention, without departing from the inventive concept, including square, circular, and oval, or even customised non-standard shapes.

In a preferred form of the present invention, the rigid outer shell and the flexible membrane will be moulded as one part, for example utilising a compression over-moulding process to mould the flexible membrane in a suitable material upon the outer shell.

The flexible membrane, whether over-moulded or formed separately to the outer shell, includes a plurality of inwardly projecting, elastically deformable abutments configured to compress against the at least one printed circuit board to provide vibration resistance. In a preferred form, the deformable abutments project inwardly from the interior surface of the flexible membrane, which in the embodiments described above would be the interior surface of the top member of the flexible membrane. In this respect, the abutments are ideally integrally formed in the flexible membrane, such as by moulding the membrane in one piece using traditional moulding techniques, to form a single, integrated, flexible membrane.

The flexible membrane may be formed from any suitable elastically deformable material, which is preferably also temperature resistant and chemically resistant to the types of chemicals that would normally be found in the engine bay of a vehicle, and which is transparent (in part or in full) for reasons that will be explained below. For example, the flexible membrane will ideally be formed from a cross-linking thermoset resin such as liquid silicone rubber (LSR), preferably a high-purity, two-component platinum-cured silicone, in the form of a viscous but pumpable material suitable for use in liquid injection moulding and formulated for the production of flexible membranes where strength and chemical resistance are desirable. For LSRs, additional heat applied once the initial cure (cross-linking due to vulcanisation) has taken place during moulding, does not affect the materials properties. It can also be moulded in a clear and flexible grade, in a very wide range of Durometers.

Alternatively, thermoforming polymers such as Thermosetting Polyurethanes (TPU) may be used as they tend to possess similar mechanical and optical properties as LSRs but TPUs might have limited use in automotive applications, especially under bonnet, due to a lesser thermal and compression set performance. Also, TPUs are more likely to age and become brittle in typical automotive operational environments, so while these types of materials could be used for the flexible membrane of the housing assembly of the present invention, they would tend to only be suitable in applications where the material can continue to perform as required for the in-service duration.

Polyurethanes (PU) are another family of catalysed two-part thermosetting materials that might be suitable for use for the flexible membrane of the housing assembly of the present invention, having a wide range of desirable material properties. However, the processing of PU is normally aligned with medium to low production volumes, as opposed to injection moulded LSR which suits high-volume processes.

Furthermore, in some embodiments it might be advantageous to utilise an elastically deformable material that is resealable when punctured, such as the materials used to form septum seals which may be punctured by a sharp needle or the like and then will re-seal once the needle is removed. Such materials can be combinations of compounds such as a polytetrafluoroethylene (PTFE), polyethylene, polypropylene, rubber and silicone. In this respect, particularly suitable materials might be compression moulded out of silicone or butyl rubber in multi-cavity moulds within a highly controlled manufacturing environment. Other materials might include a chemical barrier layer, most commonly PTFE, or in extreme cases, two barrier layers.

In the present invention, LSR is advantageous due to it being durable with long-term stability and chemical resistance. LSR is also compatible with a wide spectrum of temperatures, from −60° C. to +250° C., thus being able to maintain its high-performance mechanical properties, and its electrical properties make it ideal for insulation and conductivity protection. It also produces elastically deformable parts that are substantially transparent and can be formed in a manner such that a portion of a part can be transparent while other portions are opaque and/or are coloured, such as may be possible by utilising a two-shot moulding process.

The abutments of the flexible membrane of the housing assembly of the present invention may be of any suitable shape and configuration, preferably such that, when the housing is assembled, the abutments compress against various parts of an enclosed printed circuit board (PCB) to assist with holding those parts and avoiding undesirable vibration or movement of those parts during use. In this respect, the abutment shape and configuration may thus be customised across the interior surface of the top member of the flexible membrane, such that abutments of a suitable size and configuration compress against and hold appropriate parts of the PCB, or the abutments may be regular and standardised to compress and hold any part of the PCB that the abutments contact when the housing is assembled.

The abutments may thus be in the form of an array of cells, preferably similarly sized and shaped, such as hexagonal cells forming a honeycomb structure on the interior surface of the top member of the flexible membrane. Alternatively, the cells may be circular, oval, square, rectangular, pentagonal, heptagonal, or octagonal as desired. Again, and as foreshadowed above, some regions of the array of cells may be cells of a certain shape, with other cells in a different region being of a different shape, with some cells also being of different heights, thus projecting to further extents away from the interior surface of the top member of the flexible membrane.

In another form, the abutments may be a series of ribs projecting away from the interior surface of the top member of the flexible membrane, with the ribs being spaced from each other by a suitable amount and being of a suitable height off the interior surface. Again, the series of ribs may be of different spacings and heights and may be adopted in conjunction with an array of cells of the types mentioned above, allowing for customisation of the abutments to suit particular PCBs if desired.

The presence of the abutments on the flexible membrane allows for the flexible membrane to provide physical protection to a PCB housed in the assembly, without the need for the PCB to undergo potting or conformal coating to fully encapsulate the PCB and its components within a moulded silicone. Vibration and/or oscillation of the components is dampened by the flexible membrane, which increases the service life of the components, for example by reducing the amount of stress applied to their solder joints. Removing the need to pot the PCB fully in silicone also removes a time consuming and costly process, particularly in high volume production runs.

Amongst, or in addition to, the abovedescribed abutments of the flexible membrane, the flexible membrane may advantageously include other integral formations such as one or more light pipes and/or one or more pressure testing ports.

Light pipes are optical components used to transport light from a PCB mounted LED, for example, to a point where the light is required, such as exterior to the housing assembly of the present invention so that the LED is visible to a user when lit. In this respect, the outer shell of the housing assembly would then ideally include cooperating openings aligned with the light pipes of the flexible membrane to permit the LED to be visible through the outer shell.

In a preferred form, the housing assembly of the present invention will also include a testing port that would permit the seal of the housing assembly to be tested after manufacture but before distribution and sale, such as by the inclusion in the flexible membrane of a formation in the form of a port through which a pressurised gas may be injected to test for leakage, or alternatively through which a vacuum may be applied. In a preferred form, the outer shell would then ideally include a cooperating opening aligned with the testing port of the flexible membrane to permit the pressurised gas to be urged into the enclosure after assembly, with the cooperating opening being permanently closable after testing by way of a cover plug or the like.

Alternatively, such a testing port may instead be provided by a testing injection site, such as might be preferred if the material of the flexible membrane was selected such that this testing could be conducted by way of a septa-style needle piercing (as mentioned above) in the testing injection site,

In one embodiment, the testing port (and indeed a testing injection site in that embodiment) in the flexible membrane can be provided with a surrounding bellows formation to permit the testing port to be distorted or flexed into position during assembly without the possibility of over elongating (stretching) the material of the flexible membrane. While LSR, for example, does haves an extremely high elongation at break (300 to 810% dependent on the material) and the risk of tearing is thus extremely low, ease of assembly is important for keeping assembly time to a minimum. Such a bellows formation may also provide further flex in the membrane which can assist with providing the membrane with pressure compensation benefits.

Additionally, the flexible membrane may also include one or more programme control buttons, preferably formed integrally within a portion of the flexible membrane. Such control buttons are preferably “soft-touch” buttons, ideally operable in conjunction with surface mounted microswitches which allow a user to trigger specific functions (eg blue tooth linking, test modes etc) in the housing assembly.

In this form, the flexible membrane may be thinned out in a section to allow controlled flexibility in the direction of a surface mounted microswitch, adjacent to a thicker section allowing a push force to be transferred to detent the microswitch. By selecting a suitable gap, and a microswitch with the correct activating force, a programme control button with acceptable tactile feedback for a user can be provided. In this respect, the use of LSR as the material of the flexible membrane can prevent overloading of microswitches, due to the inherent flexibility of the LSR, for instance if suitable limit points are included in the configuration of any included programme control buttons.

Of course, it will also be appreciated that the combination of a light pipe feature, utilising a transparent portion of the flexible membrane, with suitable programme control button(s), can provide illuminated indications for the control buttons, while also still achieving the desired IP-rated seal and vibration resistance achieved with the housing assembly of the present invention.

Finally with respect to the flexible membrane and its preferred features and configuration, it will also be appreciated that the flexible membrane is able to be formed to create labyrinth seals and/or o-ring style lip seals, and to fit around terminals and other physical features of the base member or the PCB, all within the enclosure formed between the base member and the outer shell and also through any part of the flexible membrane that might extend between and beyond the outer shell and the base member, such as via externally extending portions thereof, ideally at either or both ends of the housing assembly.

The housing assembly of the present invention may thus be advantageously adopted for use in providing IP-rated protective enclosures which permit the continuous operation of electrical/electronic components within products which are installed and operated within environments that are typically detrimental to the continuous operation and service life of these components, while still ideally facilitating user inputs and feedback of system status without requiring any disassembly or removal of protective covers or housings.

### BRIEF DESCRIPTION OF DRAWINGS

Having briefly described the general concepts involved with the present invention, two preferred embodiments of an electronics housing assembly will now be described that are in accordance with the present invention. However, it is to be understood that the following description is not to limit the generality of the above description.

In the drawings:

FIGS. 1(a), 1(b) and 1(c) are isometric views from above (FIGS. 1(a) and 1(b)) and below (FIG. 1(c)) of an outer shell for a first embodiment of a housing assembly in accordance with the present invention;

FIG. 1(d) is an isometric view from below of an outer shell with an over-moulded flexible membrane (shown in FIG. 1(e) with the outer shell separated from the flexible membrane for illustration purposes) for a second embodiment of the present invention;

FIG. 2 is an isometric view from above of a base member for use with either the first or second embodiment;

FIGS. 3(a), 3(b) and 3(c) are isometric views from above (FIGS. 3(a) and 3(b)) and below (FIG. 3(c)) of a flexible membrane for use with the first embodiment;

FIGS. 4(a), 4(b) and 4(c) are an isometric view from above (FIG. 4(a)), a top view (FIG. 4(b)) and a schematic isometric view (FIG. 4(c)) of an assembled housing assembly in accordance with the first embodiment;

FIG. 4(d) is a schematic isometric view of an assembled housing assembly in accordance with the second embodiment;

FIGS. 5(a) and 5(b) are a schematic isometric view (FIG. 5(a)) of the housing assembly of the first embodiment, with a breakaway portion (FIG. 5(b)) showing deformable abutments of the flexible membrane compressed against a PCB; and

FIGS. 6(a) and 6(b) schematically illustrates a light tube and programming control formed within the flexible membrane and outer shell of the housing assembly of the first embodiment.

### DETAILED DESCRIPTION OF THE PREFERRED EMBODIMENTS

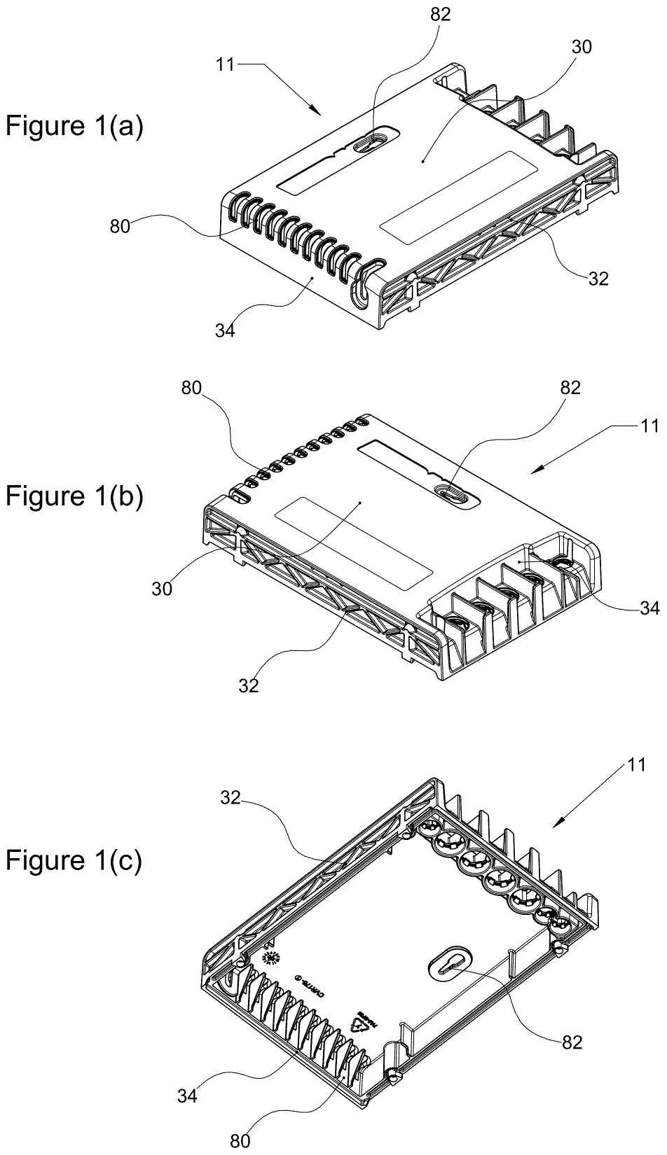

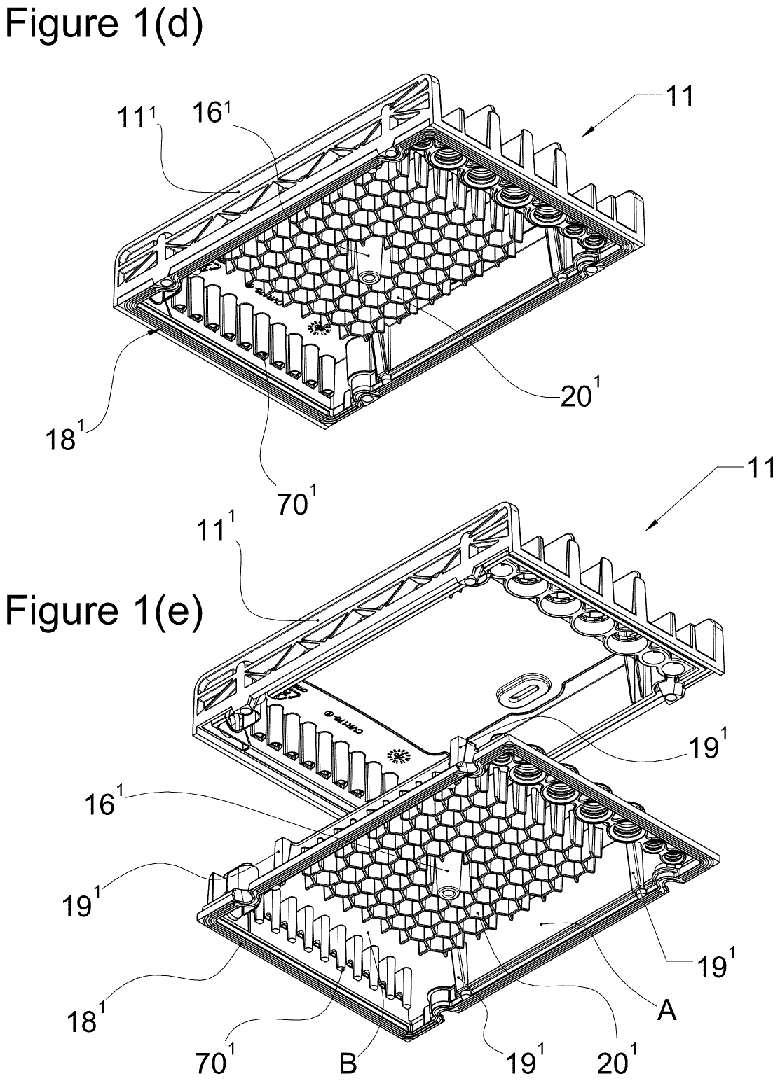

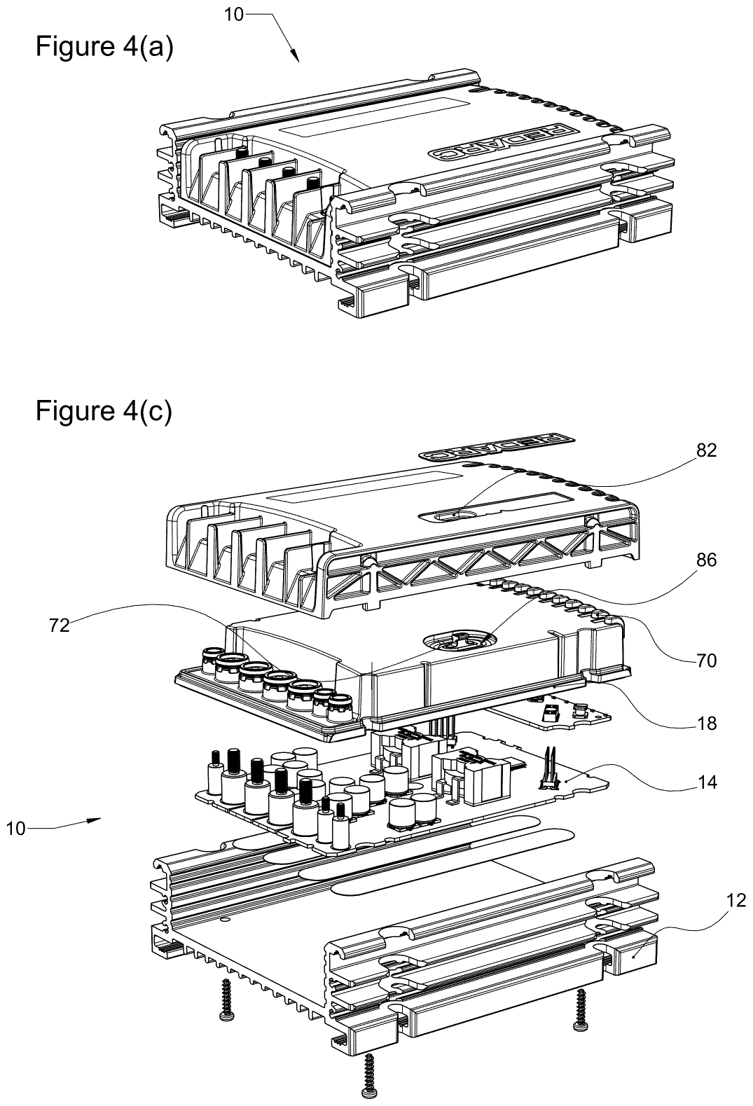

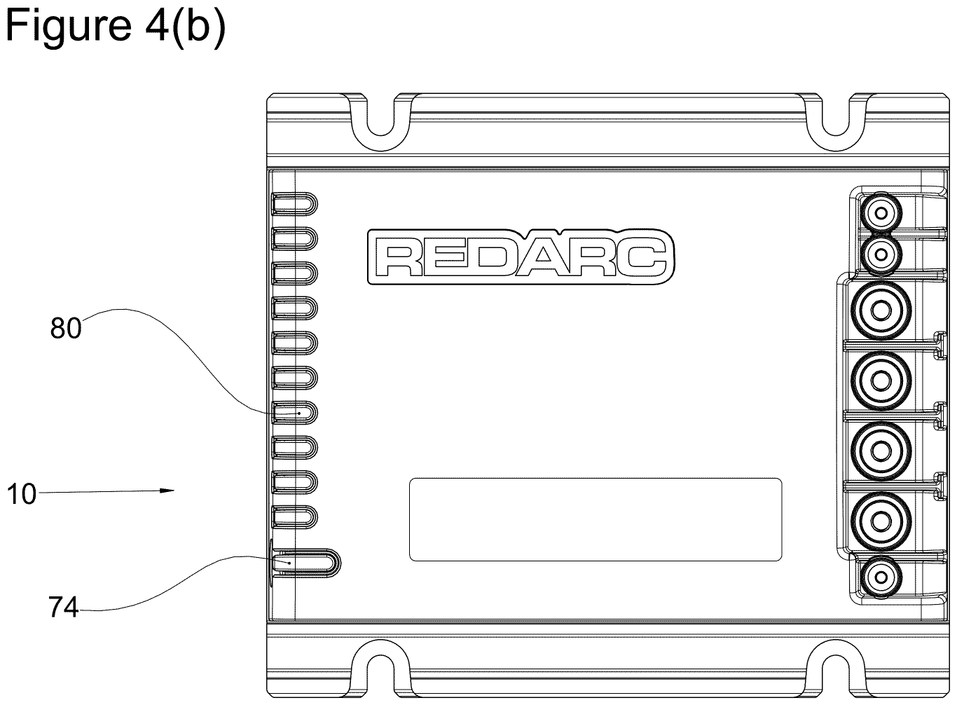

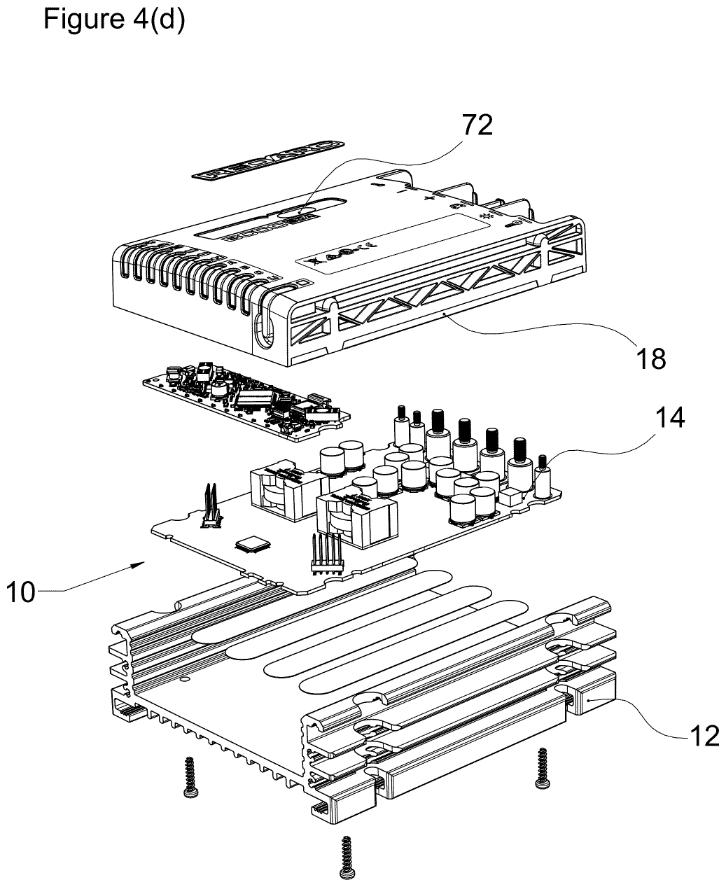

Illustrated separately in the images of FIGS. 1, 2 and 3 are the components of an electronics housing assembly, before assembly of the components into the housing assembly, in accordance with two preferred embodiments of the present invention, with an assembled housing assembly evident in each of the images of FIGS. 4, 5 and 6 and particularly in FIGS. 4(a), 4(b) and 4(c).

The difference between the two preferred embodiments lies primarily in the formation of the flexible membrane of the housing assembly, which in the first embodiment is formed as a separate element to the outer shell and the base member, but in the second embodiment (FIGS. 1(d), 1(e) and 4(d)) is formed using an over-mould process in association with the outer shell. The distinctions between the two embodiments will be highlighted below—it will be appreciated that both embodiments are in accordance with the present invention.

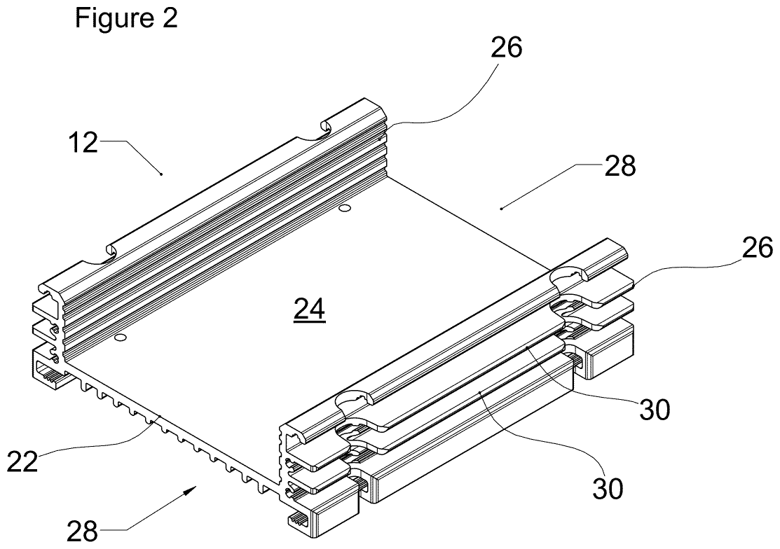

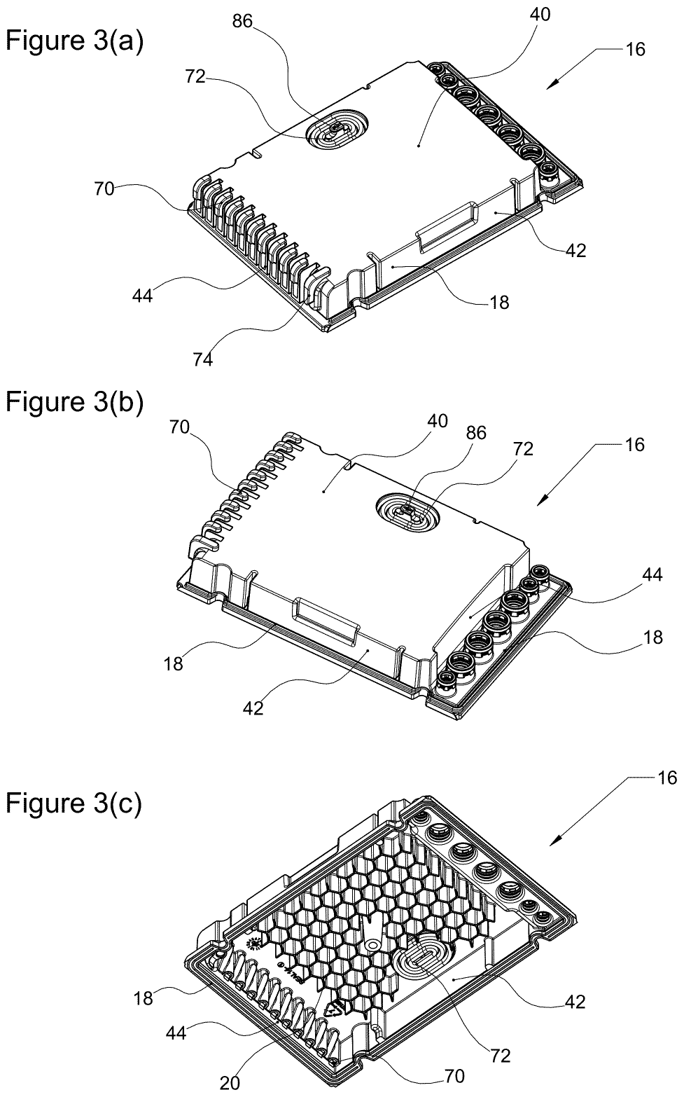

With reference firstly to the images in FIGS. 1, 2 and 3, illustrated in FIGS. 1(a), 1(b) and 1(c) is a rigid outer shell 11, in FIG. 2 is a rigid base member 12 for mounting at least one printed circuit board 14 thereto (see FIG. 4(c)), and in FIGS. 3(a), 3(b) and 3(c) is a flexible inner sealing membrane 16 in accordance with the first embodiment. In this respect, the base member 12 and the outer shell 11 together form an enclosure for a printed circuit board (PCB) (item 14 in FIGS. 4(c) and 4(d)), while the flexible membrane 16 is configured to lie in between the base member 12 and the outer shell 11.

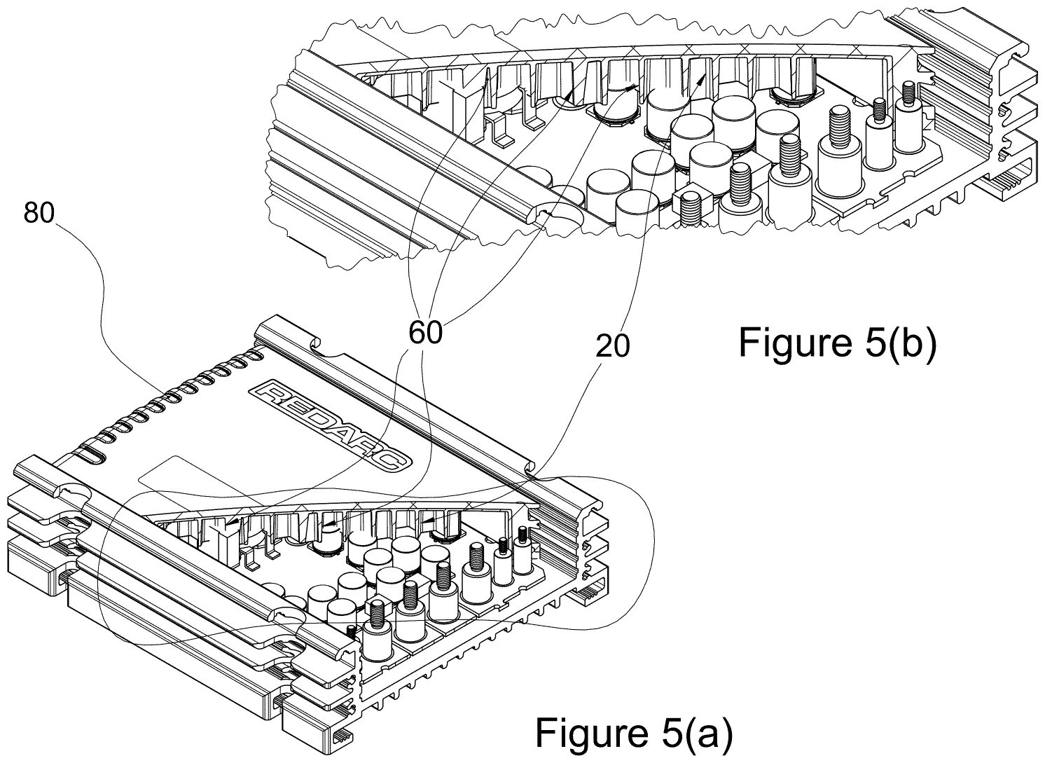

In FIGS. 3(a), 3(b) and 3(c), the flexible membrane 16 of the first embodiment includes a sealing portion 18 about its periphery for compression between the base member 12 and the outer shell 11 to seal the enclosure. The flexible membrane 16 also includes a plurality of inwardly projecting, elastically deformable abutments 20 configured to compress against the PCB 14 (the compression being evident in FIGS. 5(a) and 5(b)) to provide vibration resistance for the PCB 14 and its various components.

In FIG. 2, the base member 12 for both embodiments includes a rectangular bottom portion 22 whose upper surface 24 provides a PCB 14 mounting surface, with the bottom portion 22 including opposed upstanding side walls 26 and being open at its ends 28. The side walls 26 include integrated external heat sink arrangements in the form of elongate heat dissipating fins 30, the fins 30 being configured longitudinally along the exterior of the side walls 26 to assist with heat removal from the enclosure of the housing assembly 10 during use.

As can be seen in FIGS. 1(a) to 1(c), the outer shell 11 is box-shaped, also having a rectangular shape, but with a top portion 30 having downwardly extending perimetric side walls 32 and end walls 34 about its periphery. The outer shell's side walls 32 are opposed and are spaced and sized to fit inside the side walls 26 of the base member 12, with the top portion 30 of the outer shell 10 itself being sized such that its end walls 34 can be positioned adjacent the ends 28 of the bottom portion 22 of the base member 12 such that the base member 12 and the outer shell 11 together form the enclosure of the housing assembly.

Therefore, prior to assembly, but with reference to the horizontal orientation referred to above, the box-shape of the outer shell 11 renders the outer shell 11 open downwardly (per the drawings in the Figures) so as to be capable of sitting over and encapsulating, after assembly, whatever electronics are mounted on the PCB mounting surface of the bottom portion 22 of the base member 12.

The flexible membrane 16 of the housing assembly 10 is also rectangular and is also of a downwardly open box-shape. The flexible membrane 16 includes its own top member 40 with downwardly extending perimetric side walls 42 and end walls 44 about its periphery, all sized to fit, when assembled, within the outer shell 10.

The flexible membrane 16 includes the sealing portion 18 about its periphery for compression between the base member 12 and the outer shell 11 to seal the enclosure when assembled, the sealing portion 18 being an outwardly projecting peripheral sealing flange at the free ends of the walls 42,44 of the flexible membrane 16. It can also be seen that the sealing portion 18 is sized and positioned to locate between the free edge about the periphery of the outer shell 11 and the bottom portion 22 of the base member 12 when together, for compression between the base member 12 and the outer shell 11 to seal the enclosure.

In the second embodiment, its flexible membrane 16′ can be seen in FIG. 1(d) over-moulded onto the inside of its outer shell 11′, still with a sealing portion 18′ about its periphery for compression between the base member 12 and the outer shell 11 to seal the enclosure, and still with a plurality of inwardly projecting, elastically deformable abutments 20′ configured to compress against the PCB 14. The schematic version of this embodiment illustrated in FIG. 1(e) is provided to show the preferred structure of columnar members 19′ of the flexible membrane 16′ when this over-moulding embodiment is adopted, the columnar members 19′ essentially replacing the side walls and end walls 32,34 of the first embodiment as support for the sealing portion 18′.

In this respect, and to be clear, the areas marked A and B in the flexible membrane 16′ of FIG. 1(e) are openings in the flexible membrane 16′ where there would have been walls in the flexible membrane 16 of the first embodiment. Indeed, the illustration of FIG. 1(e) is only being provided to clearly show this aspect of the over-moulding embodiment, given that the flexible membrane 16′ will not ordinarily actually be separable from the outer shell 11 once it is over-moulded thereon.

As will be understood from the following description, all of the other described and illustrated elements of the flexible membrane 16 of the first embodiment may also be provided as elements of the flexible membrane 16′ of the second embodiment.

The flexible membranes 16,16′ include the deformable abutments 20,20′ configured to compress against the PCB 14 to provide vibration resistance. In the first embodiment, but relevant to both embodiments, and referring more specifically to the drawings of FIGS. 3(c), 5(a) and 5(b), the deformable abutments 20 project inwardly from the interior surface of the top member 40 of the flexible membrane 16. The abutments 20 are integrally formed in the flexible membrane 16 and the flexible membrane 16 is formed from a cross-linking thermoset resin such as liquid silicone rubber (LSR),

The abutments 20 are in the form of an array of similarly sized and shaped hexagonal cells that form a honeycomb structure on the interior surface of the top member 40 of the flexible membrane 16. In FIGS. 5(a) and 5(b), the abutments 20 can be seen compressed against various parts of the PCB 14 to assist with holding those parts and avoiding undesirable vibration or movement of those parts during use. Reference is specifically made to the several abutments referenced by the numeral 60 in those drawings where this compression can be seen.

As mentioned above, the abutment shape and configuration may be customised across the interior surface of the top member 40 of the flexible membrane 16 (and the flexible membrane 16′ of the second embodiment), such that abutments of a suitable size and configuration compress against and hold appropriate parts of the PCB 14, or the abutments may be regular and standardised to compress and hold any part of the PCB 14 that the abutments contact when the housing 10 is assembled. Thus, some regions of an array of cells may be cells of a certain shape, with other cells in a different region being of a different shape, with some cells also being of different heights, thus projecting to further extents away from the interior surface of the top member of the flexible membrane.

In the first embodiment, the flexible membrane 16 also includes other integral formations such as light pipes 70, a pressure testing port 72 and a programme control button 74.

The light pipes 70 are optical components used to transport light from an LED mounted on the PCB 14 to the exterior of the housing assembly 10 through the outer shell 11. In this respect, the outer shell 11 of the housing assembly 10 includes cooperating openings 80 aligned with the light pipes 70 of the flexible membrane 16 when the components are assembled to permit the LED to be visible through the outer shell 11.

The testing port 72 permits the seal of the housing assembly 10 to be tested after manufacture but before distribution and sale, and in this embodiment is a formation in the form of a port (as opposed to the use of a testing injection site as mentioned above as a septa alternative for testing) through the flexible membrane through which a pressurised gas may be injected after assembly to test for leakage. The outer shell 11 includes a cooperating opening 82 aligned with the testing port 72 of the flexible membrane 16 when assembled to permit pressurised gas to be urged into the enclosure after assembly, with the cooperating opening 82 then being permanently closable after testing by way of a cover plug or the like (not shown). Alternatively, and as mentioned above, this testing may occur by applying a vacuum to the enclosure.

In the first embodiment, but not the second embodiment, the testing port 72 in the flexible membrane 16 is also provided with a surrounding bellows formation 86 to permit the testing port 72 to be distorted or flexed into position during assembly without the possibility of over elongating (stretching) the material of the flexible membrane. Such a bellows formation 86 also provides further flex in the membrane 16 which can assist with providing the membrane 16 with pressure compensation benefits during use.

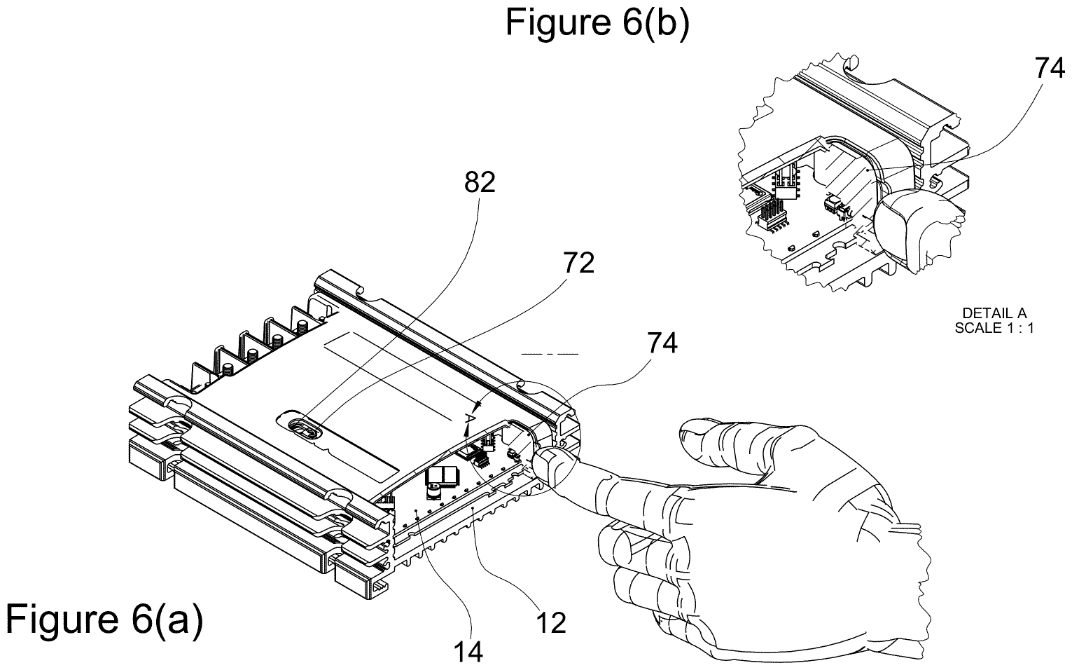

In the first embodiment, the flexible membrane 16 also includes a programme control button 74, again formed integrally within a portion of the flexible membrane 16. The control button 74 is a “soft-touch” button, operable in conjunction with surface mounted microswitches on the PCB which allow a user to trigger specific functions (eg blue tooth linking, test modes etc) in the housing assembly 10. The operation of such a control button 74 can be seen in FIGS. 6(a) and 6(b).

In conclusion, it must be appreciated that there may be other variations and modifications to the configurations described herein which are also within the scope of the present invention

1. An electronics housing assembly including a rigid base member for mounting at least one printed circuit board thereto, a rigid outer shell, and a flexible inner sealing membrane, the base member and the outer shell together forming an enclosure for the at least one printed circuit board, wherein the flexible membrane includes:
a sealing portion about its periphery for compression between the base member and the outer shell to seal the enclosure; and
a plurality of inwardly projecting, elastically deformable abutments configured to compress against the at least one printed circuit board to provide vibration resistance.

2. An assembly according to claim 1, wherein the rigid base member includes a bottom portion whose upper surface provides a mounting surface for the printed circuit board, with the bottom portion including opposed upstanding side walls and being open at its ends.

3. An assembly according to claim 2, wherein the side walls include an integrated external heat sink arrangement in the form of elongate heat dissipating fins, the fins configured preferably longitudinally along the exterior of the side walls.

4. An assembly according to claim 1, wherein the outer shell is box-shaped with a top portion having downwardly extending perimetric side walls and end walls about its periphery.

5. An assembly according to claim 4, wherein the outer shell's side walls are opposed and are spaced and sized to fit inside the side walls of the base member, with the top portion of the outer shell itself being sized such that its end walls can be positioned adjacent the ends of the bottom portion of the base member such that the base member and the outer shell together form the enclosure of the housing assembly.

6. An assembly according to claim 1, wherein the flexible membrane is box-shaped with a top member with downwardly extending perimetric side walls and end walls, and/or columnar members, about its periphery, all sized to fit within the outer shell.

7. An assembly according to claim 6, wherein the flexible membrane includes a sealing portion about its periphery for compression between the base member and the outer shell to seal the enclosure when assembled.

8. An assembly according to claim 7, wherein the sealing portion is an outwardly projecting peripheral sealing flange at the free ends of the walls and/or columnar members of the flexible membrane, sized and positioned to locate between the free ends of the outer shell and the bottom portion of the base member when together, for compression between the base member and the outer shell to seal the enclosure.

9. An assembly according to claim 1, wherein the flexible membrane includes a plurality of inwardly projecting, elastically deformable abutments configured to compress against the at least one printed circuit board to provide vibration resistance.

10. An assembly according to claim 9, wherein the deformable abutments project inwardly from an interior surface of the top member of the flexible membrane.

11. An assembly according to claim 10, wherein the abutments are integrally formed in the flexible membrane.

12. An assembly according to claim 9, wherein the shape and configuration of the abutments is customised across the interior surface of the top member of the flexible membrane, such that abutments of a suitable size and configuration compress against and hold appropriate parts of the printed circuit board when the housing is assembled.

13. An assembly according to claim 9, wherein the shape and configuration of the abutments is regular and standardised so as to compress and hold any part of the printed circuit board that the abutments contact when the housing is assembled.

14. An assembly according to claim 12, wherein the abutments are in the form of an array of cells.

15. An assembly according to claim 14, wherein the cells are similarly sized and shaped.

16. An assembly according to claim 14, wherein the cells are hexagonal cells forming a honeycomb structure on the interior surface of the top member of the flexible membrane.

17. An assembly according to claim 16, wherein the cells are circular, oval, square, rectangular, pentagonal, heptagonal, or octagonal.

18. An assembly according to claim 9, wherein the abutments are a series of ribs projecting away from the interior surface of the top member of the flexible membrane.

19. An assembly according to claim 18, wherein the series of ribs are of different spacings and heights, and are optionally adopted in conjunction with an array of cells, allowing for customisation of the abutments to suit particular printed circuit boards.

20. An assembly according to claim 9, wherein the flexible membrane includes integral formations in the form of one or more light pipes and/or one or more pressure testing ports.

21. An assembly according to claim 20, wherein the light pipes are optical components for transporting light from a printed circuit board mounted LED to exterior of the housing assembly so that the LED is visible to a user when lit.

22. An assembly according to claim 21, wherein the outer shell includes cooperating openings aligned with the light pipes so as to permit the LED to be visible through the outer shell.

23. An assembly according to claim 9, including in the flexible membrane a formation in the form of a testing port through which a pressurised gas may be injected to test for leakage or a vacuum may be applied to test for leakage.

24. An assembly according to claim 23, wherein the outer shell includes a cooperating opening aligned with the testing port to permit pressurised gas to be urged into the enclosure after assembly, or to permit a vacuum to be applied after assembly, with the cooperating opening being permanently closable after testing by way of a cover plug or the like.

25. An assembly according to claim 24, wherein the testing port is provided with a surrounding bellows formation.

26. An assembly according to claim 9, including in the flexible membrane a testing injection site through which a pressurised gas may be injected to test for leakage or a vacuum may be applied to test for leakage.

27. An assembly according to claim 26, wherein the outer shell includes a cooperating opening aligned with the testing injection site to permit pressurised gas to be urged into the enclosure after assembly, or to permit a vacuum to be applied after assembly, with the cooperating opening being permanently closable after testing by way of a cover plug or the like.

28. An assembly according to claim 27, wherein the testing injection site is provided with a surrounding bellows formation.

29. An assembly according to claim 1, wherein the flexible membrane is formed from liquid silicone rubber.

30. An assembly according to claim 13, wherein the abutments are in the form of an array of cells.

31. An assembly according to claim 30, wherein the cells are similarly sized and shaped.

32. An assembly according to claim 30, wherein the cells are hexagonal cells forming a honeycomb structure on the interior surface of the top member of the flexible membrane.

33. An assembly according to claim 32, wherein the cells are circular, oval, square, rectangular, pentagonal, heptagonal, or octagonal.
